(19) United States
(12) Patent Application Publication
(10) Pub. No.: US 2014/0354313 A1
(43) Pub. Date: Dec. 4, 2014

(54) Method for Temporary Electrical Contacting of a Component Arrangement and Apparatus Therefor

(71) Applicants: Michael Kuehnelt, Regensburg (DE); Roland Enzmann, Regensburg (DE)

(72) Inventors: Michael Kuehnelt, Regensburg (DE); Roland Enzmann, Regensburg (DE)

(73) Assignee: OSRAM Opto Semiconductors GmbH, Regensburg (DE)

(21) Appl. No.: 14/345,113

(22) PCT Filed: Sep. 12, 2012
(86) PCT No.: PCT/EP2012/067806

§ 371 Date: Apr. 14, 2014

(30) Foreign Application Priority Data
Sep. 14, 2011 (DE) 10 2011 113 430.5

(51) Int. Cl. G01R 1/067; G01R 31/28

(52) U.S. Cl. CPC G01R 1/067; G01R 31/2855
USPC 324/750.05; 324/754.03; 324/756.01

(57) ABSTRACT

A method for temporary electrical contacting of a component arrangement with a plurality of contact surfaces is described. A connection support includes a plurality of connection surfaces, on which contact protrusions are disposed. The connection support and component arrangement are brought together in such a way that the connection surfaces and the associated contact surfaces overlap in a top view and the contact protrusions form an electrical contact with respect to the contact surfaces in order to achieve electrical contacting of the component arrangement. Subsequently the connection support and the component arrangement are separated from each other.

This patent application is a national phase filing under section 371 of PCT/EP2012/067806, filed Sep. 12, 2012, which claims the priority of German patent application 10 2011 113 430.5, filed Sep. 14, 2011, each of which is incorporated herein by reference in its entirety.

### TECHNICAL FIELD

The present patent application relates to a method for electrical contacting of a component arrangement and an apparatus for carrying out the method.

### BACKGROUND

Electronic or optoelectronic components are often temporarily contacted in order to carry out test or burn-in processes. For this purpose it is possible to use, for example, probe cards, arrangements of spring contact pins or test bases with spring contact pins. These processes, however, are comparatively expensive, which has a negative impact especially in the case of processes in which a large number of electrical contacts are to be made simultaneously. Furthermore, in particular, when using spring contact pins, the space between surfaces which may be contacted simultaneously is limited.

### SUMMARY OF THE INVENTION

Embodiments of the invention provide a method of electrical contacting, with which a large number of electrical connections may be produced reliably and inexpensively. Furthermore, an apparatus is to be provided which makes possible reliable electrical contacting.

According to one embodiment of the method, for the purpose of preferably temporary electrical contacting of a component arrangement with a plurality of contact surfaces, a connection support with a plurality of connection surfaces, on which contact protrusions are disposed, is provided. The connection support and component arrangement are fitted together in such a way that the connection surfaces and the associated contact surfaces overlap in a top view. The contact protrusions form an electrical contact with respect to the contact surfaces in order to achieve electrical contacting of the component arrangement. In particular, after a test process or a burn-in process has been carried out the connection support and the component arrangement may be separated from each other.

By means of the contact protrusions the regions are defined in which mechanical contact, particularly temporary mechanical contact, is made between an apparatus for carrying out the method and the component arrangement to be contacted.

The contact protrusions are preferably formed in each case by means of at least one contact element. The contact elements are preferably each formed in a similar way. Rapid and automated application of the contact protrusions onto the connection surfaces of the connection support is thus simplified.

Also in a preferred manner, the contact elements are connected in a mechanically stable manner to the associated connection surfaces so that the contact elements remain on the connection support during separation of the component arrangement from the connection support.

The mechanical contact between the contact protrusions and the contact surfaces of the component arrangement is preferably releasable. This means, in particular, that the contact surfaces of the component arrangement are not, or at least not substantially, damaged during separation of the connection support and the component arrangement. Also in a preferred manner during separation of the connection support and component arrangement the contact protrusions may be removed from the respective contact surface in such a way that the contact protrusions may be re-used at least once for subsequent electrical contacting with a further component arrangement. After carrying out one or a plurality of temporary contact procedures the contact protrusions may be replaced.

In a preferred embodiment, a plurality of contact elements are disposed one above another on at least one connection surface. That is to say, at least between one contact element and the connection surface at least one further contact element is disposed. The greater the number of contact elements disposed one above the other, the greater the height of the contact protrusion, i.e., the dimension of the contact protrusion in a vertical direction extending perpendicular to the main surface of the connection support.

Preferably more contact elements are disposed at least on a connection surface of the connection support than on a further connection surface of the plurality of connection surfaces. Thus in a simple manner, contacts of the component arrangement, which are located in different contact planes to each other, may be electrically contacted.

For example, the contacts of the component arrangement may be formed in a vertical direction on at least two mutually spaced contact planes. In at least one, preferably in each, contact plane or within a distance from the contact plane dictated by manufacturing tolerances, a plurality of contact surfaces are expediently located in each case.

In a preferred development, a height difference between two contact planes of the component arrangement is at least partly compensated for by means of a variation in the number of contact elements disposed one above the other. The simultaneous electrical contacting of contacts on different contact planes is thus simplified.

In a preferred embodiment, the contact elements are in the basic form of a compressed sphere. Also in a preferred manner, the contact elements contain a metal. In particular, the contact elements may contain gold or consist of gold. In a variation to this, another material may also be used, for example, aluminum or copper.

In a further preferred embodiment, the contact elements are applied to the connection support by means of a bonding process, in particular a ball-bonding process. A ball-bonding process is understood to be generally a process in which, in particular metallic, sphere-like contact elements are applied to a connection surface and are connected to the connection surface in a mechanically stable manner, in particular under the effect of ultrasound and/or mechanical pressure and/or the introduction of heat energy. In conjunction with this, a wire-bonding process is also regarded as a ball-bonding process. The sphere-like contact elements may be produced by the melting of a wire end, in particular by reason of surface tension.

The contact elements preferably have a maximum dimension between 20 μm and 100 μm inclusive. In a ball-bonding process, the maximum dimension of the contact elements may be adjusted in particular by means of the thickness and/or length of the wire end to be melted.

In a further preferred embodiment the contact protrusions have a thickness of between 20 μm and 300 μm inclusive in a direction perpendicular to a main surface of the connection support. A thickness in this range has proved to be particularly suitable for contacting of electrical and optoelectronic components.

In a further preferred embodiment, the connection support is a circuit board, in particular, a flexible circuit board. The arrangement of the connection surface on the connection support, in particular on the circuit board, is expediently adapted to the arrangement of the contact surface of the component arrangement.

In a preferred embodiment, a center-to-center distance between two adjacent contact surfaces, in particular, contact surfaces which are electrically contacted simultaneously, is at the most 0.5 mm, in a particularly preferred manner at the most 0.3 mm. Component arrangements with a comparatively high contact density may also be electrically contacted. By means of the contact protrusions, component arrangements having a center-to-center distance which would be too small for electrical contacting with conventional processes such as the use of spring contact pins may thus also be electrically contacted.

In a preferred development, the connection support is attached to a rigid support. The rigid support may be formed, for example, as a metal support. Also in a preferred manner, an elastic intermediate layer is disposed between the connection support and the rigid support. The elastic intermediate layer is preferably formed in such a way that height differences between the contact surfaces are compensated for when bringing the connection support and component arrangement together. Even in the case of a component arrangement with a plurality of components with contact surfaces which are not disposed precisely at common height levels, for example, because of manufacturing tolerances, reliable simultaneous contacting of the contact surfaces may thus be ensured.

In a further preferred embodiment, the component arrangement has a plurality of optoelectronic components, in particular, a plurality of luminescence diodes, for example, laser diodes. Also in a preferred manner, the optoelectronic components are subjected to a test process and/or a burn-in process. In a burn-in process, components are put into operation for a preset time. The process is suitable, in particular, for components with a failure rate which exhibits a bath-tub curve. That is to say, the failure rate is comparatively high shortly after coming into operation, then falls to a largely constant value and increases only towards the end of the average service life of the components.

A large number of optoelectronic components, for example, ten components or more, preferably 100 components or more, most preferably 1,000 components or more are preferably simultaneously electrically contacted and subjected to a test process and/or a burn-in process.

In accordance with one embodiment, an apparatus for preferably temporarily electrically contacting a component arrangement has a support which may move relative to a positioning surface provided for receiving the component arrangement. The support is provided on a side facing the positioning surface for attachment of a connection support.

By attaching a connection support adapted to the component arrangement which is to be electrically contacted, and by producing an electrical contact between connection surfaces of the connection support and contact surfaces of the component arrangement, electrical contacting of the component arrangement may be carried out in a simple manner.

By exchanging the connection support, the apparatus may easily be adapted to the respective contact geometry of the component arrangement.

Between the support and the connection support, an elastic intermediate layer is preferably disposed so that the connection support is adapted to the height profile of the contact surfaces of the component arrangement when pressed against the component arrangement.

The apparatus is particularly suitable for carrying out the method described further above. Features described in conjunction with the method may thus also be drawn upon for the apparatus and vice versa.

By means of the described embodiment of the contact protrusions, components, in which contact surfaces are at different height levels, may also be electrically contacted with a planar or essentially planar connection support, i.e., in the case of a connection support in which the connection surfaces are essentially located at the same height level.

Furthermore, the contact protrusions may be produced in an automated and particularly inexpensive manner.

After separation of the connection support and component arrangement, the contact protrusions preferably remain on the connection support so that the contact protrusions may be re-used in a subsequent method step for contacting a further component arrangement.

### BRIEF DESCRIPTION OF THE DRAWINGS

Further features, embodiments and expedient characteristics are given by the following description of the exemplary embodiments in conjunction with the figures.

FIGS. 1A and 1B show an exemplary embodiment for a method for electrical contacting of a component arrangement with the aid of steps illustrated schematically in a sectional view;

FIGS. 2A and 2B show an exemplary embodiment for a connection support in a schematic top view (FIG. 2A) and a section from a 3D drawing (FIG. 2B) of a connection support with contact protrusions disposed thereon in accordance with an exemplary embodiment; and

FIG. 3 shows a schematic cross-sectional view of an exemplary embodiment for an apparatus during the electrical contacting of a component arrangement.

Equivalent, similar, or equivalently operating elements are provided with the same reference numbers in the figures.

The figures and the size ratios of the elements illustrated in the figures are not be considered as being in scale with each other. It is rather the case that individual elements may be illustrated in an exaggeratedly large manner in order to be depicted and/or understood better.

### DETAILED DESCRIPTION OF ILLUSTRATIVE EMBODIMENTS

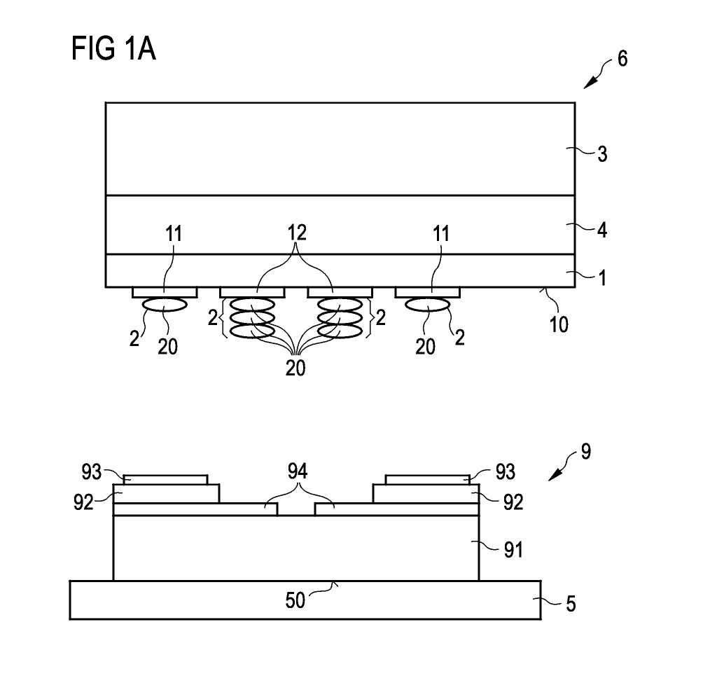

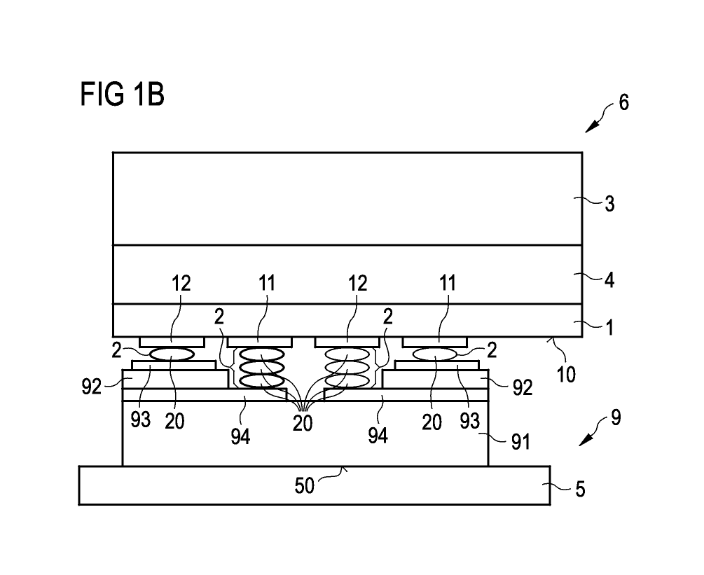

In FIG. 1A a schematic cross-sectional view of an exemplary embodiment for an apparatus 6 is shown. The method is described merely by way of example with the aid of a component arrangement 9 in which two components 92 are disposed next to each other. The components 92 are each electrically contactable by means of a first contact surface 93 and a second contact surface 94. The components 92 may be designed as semiconductor components, in particular as optoelectronic semiconductor components, for example, as luminescence diodes, such as semiconductor lasers.

In the illustrated exemplary embodiment the components 92 are disposed on an intermediate support 91. This intermediate support may be divided, after the temporary electrical contacting, for separation of the component arrangement into a plurality of components. As a deviation therefrom, the components may also be provided already singulated.

The first contact surface 93 and the second contact surface 94 are spaced apart from each other in a vertical direction and are therefore located at different height levels.

The component arrangement 9 is disposed on a positioning surface 50 of a holder 5.

The apparatus 6 has a connection support 1. The connection support is attached to a support 3. The support is preferably rigid.

Suitable materials for the rigid support 3 are, for example, a metal such as steel, a semiconductor material such as silicon or germanium, or a glass.

On a main surface 10 of the connection support 1 facing away from the support 3 a plurality of connection surfaces 11 and a plurality of further connection surfaces 12 are formed. The connection support 1 is designed in such a way that the connection surfaces 11 may be disposed overlapping with the first contact surfaces 93 of the component arrangement and the further connection surfaces 12 overlapping with the second contact surfaces 94 of the component arrangement.

A contact protrusion 2 is formed on the connection surfaces 11 and is formed by means of a single contact element 20.

The contact protrusion 2 is formed on the further connection surfaces 12 by means of three contact elements 20 in each case. These contact elements are disposed one above the other in the vertical direction.

The number of contact elements 20 on the further connection surface 12 is selected such that the different heights of the contact protrusions 2 on the connection surfaces 11 and 12 at least partly compensate for the height difference between the first contact surfaces 93 and second contact surfaces 94. Thus in a simple manner, contact surfaces at different contact levels may also be contacted in a simple and reliable manner with a connection support 1 which is planar per se, in which the connection surfaces 11, 12 are at the same level or at least essentially at the same level.

The connection support 1 is preferably formed as a circuit board, for example, as printed circuit board.

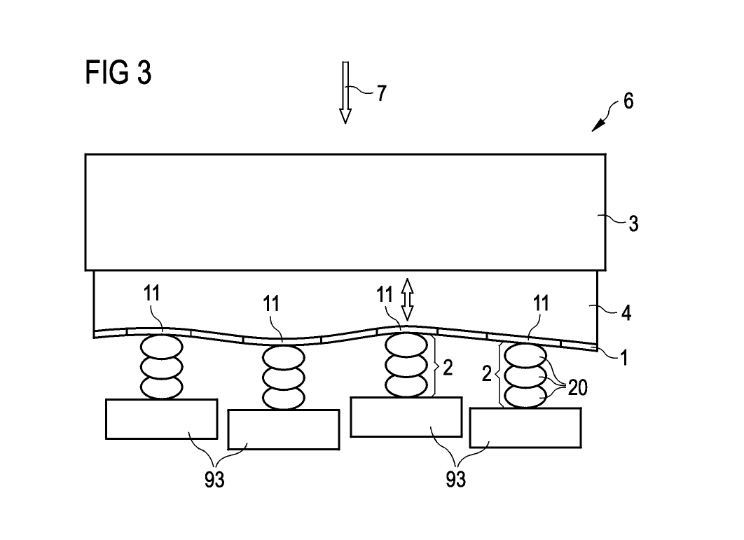

Between the connection support 1 and the support 3 an elastic intermediate layer 4 is formed. The elastic intermediate layer is provided to compensate for fluctuations in the height level between different contact surfaces of the component arrangement when the connection support 1 is being pressed against the contact surfaces 93, 94 of the component arrangement 9. This is explained in more detail in conjunction with FIG. 3.

The contact elements 20 are preferably attached to the connection surfaces 11, 12 of the connection support 1 by means of a ball-bonding process. The connection surfaces may thus easily be fitted with contact elements 20 for the contact protrusions 2 in a fully automated manner with a high level of precision and a narrow spacing. The contact elements thus typically have a basic form of a compressed sphere. Gold is particularly suitable as a material for the contact elements. However, in a deviation therefrom, aluminum or copper may also be used. Another electrically conductive material such as indium may fundamentally also be used.

As shown in FIG. 1B, the component arrangement 9 and the connection support 1 are positioned relative to each other such that the contact protrusions 2 produce an electrical contact between the connection surfaces 11, 12 and the associated contact surfaces 93, 94 of the component arrangement. The contact protrusions each directly adjoin a connection surface and directly adjoin the associated contact surface. The components of the component arrangement contacted in this manner may now be subjected to an electrical test process and/or a burn-in process.

The connection support 1 with the contact protrusions 2 may subsequently be released from the component arrangement.

With the described embodiment of the contact protrusions 2, adjacent contact surfaces on the component arrangement which have a particularly small center-to-center distance from each other may be contacted simultaneously.

The center-to-center distance of at least two adjacent contact surfaces is preferably smaller than 0.5 mm, particularly preferably smaller than 0.3 mm. In particular, the center-to-center distance may be 150 μm or less, for example, about 100 μm.

Furthermore, the contact protrusions may have a high level of robustness. That is to say, that the contact protrusions may contact component arrangements 9 one after another in a large number of measuring cycles before the contact protrusions or the whole connection support 1 have to be changed.

Furthermore, the method is characterized in that it is possible to achieve particularly low costs per contact. A throughput required for mass production may thus be achieved by a high number of connection surfaces with contact protrusions in a simple and inexpensive manner. For example, for a burn-in process for 1,400 lasers, each with two contact surfaces, all 2,800 contact surfaces may simultaneously be electrically contacted with 2,800 connection surfaces, correspondingly formed on the connection support 1, and contact protrusions 2 disposed thereon, and be subjected to the method. Even in the case of a comparatively long duration of 10 hours for a burn-in process, a throughput of 100,000 components per month may thus be achieved.

Furthermore, the connection support 1 with the connection protrusions 2 may be multiplied simply and inexpensively. By parallel use of a plurality of apparatuses 6 each with at least one such connection support 1, the throughput may be increased or the same throughput may be achieved with a smaller number of connection surfaces per connection support.

In contrast to the mechanically stable connection of the contact protrusions 2 to the connection surfaces 11, 12 of the connection support, only a temporary mechanical contact is produced with respect to the contact surfaces 93, 94 of the component arrangement 9 so that the contact protrusions remain on the connection surfaces of the connection support during removal of the connection support from the component arrangement 9 and are available for a subsequent test or burn-in process on a further component arrangement.

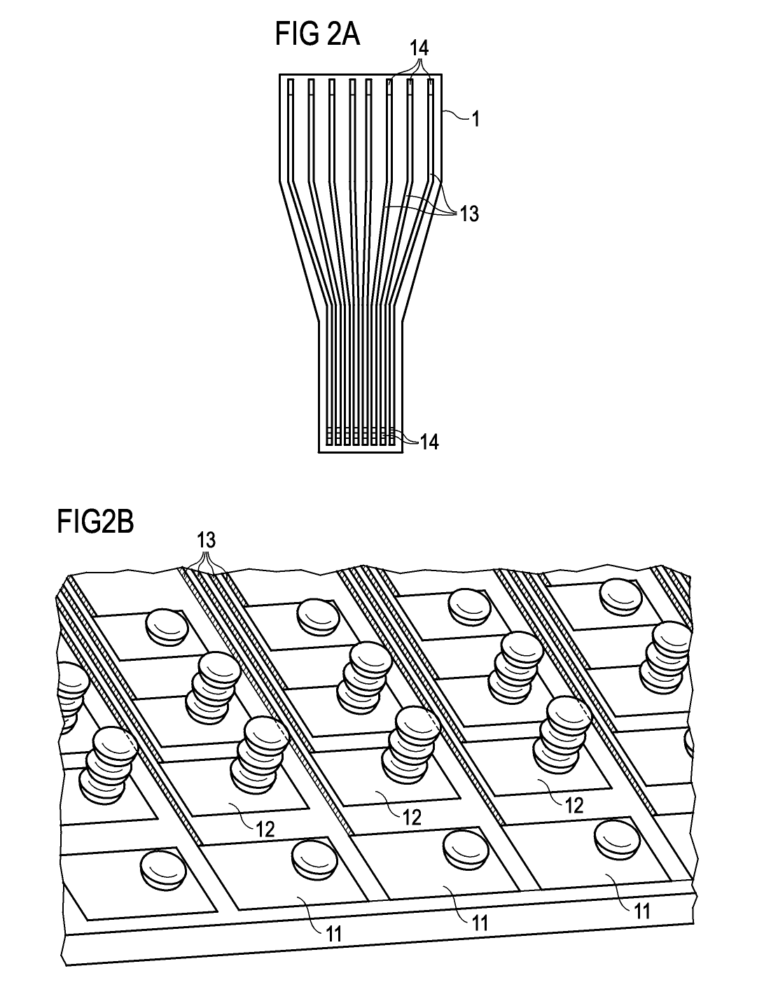

FIG. 2A shows a schematic top view of an exemplary embodiment for a connection support 1. Conducting tracks 13 are formed in the connection support 1 and at one end form the connection surfaces (not shown explicitly in FIG. 2A). At one end opposite to the connection surfaces, the conducting tracks 13 have a connection region 14. The conducting tracks 13 are each formed such that the distance between the connection regions 14 is greater than the distance between the conducting tracks in the region of the connection surfaces. Electric contacting of the connection regions with an electric control is thus simplified.

FIG. 2B shows a three-dimensional drawing of a section of a connection support 1 in which the connection surfaces 11, 12 are disposed in a matrix-like manner. As described in conjunction with FIG. 1, a contact element 20 is formed on each of the connection surfaces 11 and three contact elements 20 are formed on each of the further connection surfaces 12 so as to form the contact protrusion 2.

The number of contact protrusions may be varied within wide limits deviating from the described exemplary embodiment but in dependence upon the component arrangement to be contacted.

In a direction perpendicular to the main surface 10, the contact protrusions 2 preferably have a thickness between 20 μm and 300 μm inclusive. The thickness of a single contact element 20 is preferably between 20 μm and 100 μm inclusive, particularly preferably between 40 μm and 80 μm inclusive, for example, 50 μm. For example, by using a contact protrusion 2 with three contact elements 20 on the first connection surface 11 and a contact protrusion with one contact element on the further connection surface 12 a height difference of 100 μm between two contact levels of the component to be contacted may be achieved.

The method described is further characterized by a particularly high level of flexibility. In the case of a change to the component arrangement to be contacted, only the connection support needs to be appropriately adapted with respect to the arrangement of the connection surfaces. The precise position, height and/or number of the contact elements may easily be programmed and thus be formed on the connection surfaces in a fully automated manner.

The manner of functioning of the elastic intermediate layer 4 is shown schematically in FIG. 3 with the aid of a further exemplary embodiment schematically illustrated in cross-section. In this exemplary embodiment, contact surfaces 93 are shown schematically and are not located at precisely the same height level, for example, owing to a curvature of the intermediate support 91 of the component arrangement (see, e.g., FIG. 1A).

For example, bending of the intermediate support may lead to a height difference of 10 μm or more.

This height difference is compensated for when the connection support 1 is being pressed against the component arrangement 9, illustrated by an arrow 7, so that in spite of a connection support 1, which is planar per se, and contact protrusions 2, which are essentially of the same height, with respect to the contact surfaces 93 a temporary electrical contact is reliably produced.

The elastic intermediate layer 4 is formed in such a way with respect to its thickness and elasticity that it compensates for the occurring height differences of the contact surfaces, in particular height differences between contact surfaces at nominally the same contact level, of the component arrangement.

The elastic intermediate layer 4 is preferably formed in such a way that it undergoes no, or substantially no, plastic deformation during the method. After the connection support 1 is released from the component arrangement 9, the elastic intermediate layer thus returns to its original shape. However, the elastic intermediate layer does not necessarily have to be operated in a range in which the deformation of the material of the elastic intermediate layer is proportional to the active force as long as no plastic deformation occurs.

The elastic intermediate layer is preferably formed by a material which has a modulus of elasticity between and 1 MPa and 1000 MPa inclusive, particularly preferably between 100 MPa and 1000 MPa inclusive. For example, an elastomer such as silicon or a rubber-based material is suitable. A thermoplastic or a thermosetting plastic may also be used provided an essentially elastic deformation may be achieved. For example, a polyimide may be used. A material such as this is also suitable for use at high temperatures. An adhesive, which is hardened or at least has begun to harden, may also have a suitable elasticity.

The thickness of the elastic intermediate layer may be, in particular, between 0.1 mm and 1 cm inclusive in dependence upon the material used.

In the case of a modulus of elasticity of 200 MPa and an arrangement with 200 connection surfaces, a thickness of about 1 mm is suitable, for example.

The invention is not limited by the description of the exemplary embodiments. Rather, the invention includes every new feature and every combination of features, which contains, in particular, every combination of features in the claims, even if this feature or this combination is not explicitly stated in the claims or in the exemplary embodiments.

1-15. (canceled)

16. A method for temporary electrical contacting of a component arrangement with a plurality of contact surfaces, the method comprising:
providing a connection support with a plurality of connection surfaces, on which contact protrusions are disposed;
bringing together the connection support and component arrangement in such a way that the connection surfaces and associated contact surfaces overlap in a top view and the contact protrusions form an electrical contact with respect to the contact surfaces in order to achieve electrical contacting of the component arrangement; and
separating the connection support and the component arrangement.

17. The method as claimed in claim 16, wherein a plurality of contact elements are disposed one above the other on at least one connection surface.

18. The method as claimed in claim 17, wherein the contacts of the component arrangement are formed on a plurality of contact planes in a vertical direction.

19. The method as claimed in claim 18, wherein a height difference between two contact planes of the component arrangement is at least partly compensated for by a variation in the number of contact elements disposed one above the other.

20. The method as claimed in claim 16, wherein each contact protrusion is formed by at least one contact element.

21. The method as claimed in claim 20, wherein the contact elements are each formed as a compressed sphere.

22. The method as claimed in claim 20, wherein the contact elements are applied to the connection support by a ball-bonding process.

23. The method as claimed in claim 16, wherein the contact protrusions have a thickness of between 20 μm and 300 μm inclusive in a direction perpendicular to a main surface of the connection support.

24. The method as claimed in claim 16, wherein the connection support comprises a flexible circuit board.

25. The method as claimed in claim 16, wherein the connection support is attached to a rigid support and an elastic intermediate layer is disposed between the connection support and the rigid support and is formed in such a way that height differences between the contact surfaces are compensated for when bringing together the connection support and the component arrangement.

26. The method as claimed in claim 16, wherein a center-to-center distance between two adjacent contact surfaces is at most 0.5 mm.

27. The method as claimed in claim 16, wherein the component arrangement has a plurality of optoelectronic components, the method further comprising subjecting the optoelectronic components to a test process and/or a burn-in process prior to the separating.

28. An apparatus for temporarily electrically contacting a component arrangement, the apparatus comprising a support that can move relative to a positioning surface provided for receiving the component arrangement, wherein the support is provided on a side facing the positioning surface for attachment of a connection support.

29. The apparatus as claimed in claim 28, wherein an elastic intermediate layer is disposed between the connection support and the support.

30. The apparatus as claimed in claim 28, wherein the apparatus includes the connection support attached to the support, the apparatus further comprising a plurality of connection surfaces overlying a planar surface of the connection support, each connection surface including a contact protrusion and each contact protrusion including one or more contact elements, wherein a first contact protrusion comprises a first number of contact elements vertically stacked one above the other in a direction extending away from the connection support and wherein a second contact protrusion comprises a second number of contact elements vertically stacked one above the other in the direction extending away from the connection support, wherein the second number is different than the first number and wherein a difference between the first and second numbers is based on a height difference of different portions of the component arrangement that is temporarily electrically contacted.

31. The apparatus as claimed in claim 30, wherein each contact element has the shape of a compressed sphere.

32. The apparatus as claimed in claim 30, wherein the connection support comprises a printed circuit board, the apparatus further comprising an elastic intermediate layer disposed between the support and the connection support.

33. A method for temporary electrical contacting of a component arrangement with a plurality of contact surfaces, the method comprising:
providing a connection support with a plurality of connection surfaces, on which contact protrusions are disposed;
bringing together the connection support and the component arrangement in such a way that the connection surfaces and associated contact surfaces overlap in a top view and the contact protrusions form an electrical contact with respect to the contact surfaces in order to achieve electrical contacting of the component arrangement, wherein the component arrangement has a plurality of optoelectronic components;
subjecting the optoelectronic components to a burn-in process; and
after subjecting the optoelectronic components to the burn-in process, separating the connection support and the component arrangement.

34. The method as claimed in claim 33, wherein a failure rate of the optoelectronic components exhibits a bathtub curve.

35. The method as claimed in claim 33, wherein a plurality of contact elements are disposed one above the other on at least one connection surface;
wherein the contacts of the component arrangement are formed on a plurality of contact planes in a vertical direction; and
wherein a height difference between two contact planes of the component arrangement is at least partly compensated for by a variation in the number of contact elements disposed one above the other.
